(19) United States
(12) Patent Application Publication
(10) Pub. No.: US 2017/0012076 A1
(43) Pub. Date: Jan. 12, 2017

(54) PHOTODETECTORS BASED ON INTERBAND TRANSITION IN QUANTUM WELLS

(71) Applicant: INSTITUTE OF PHYSICS, CHINESE ACADEMY OF SCIENCES, Beijing (CN)

(72) Inventors: Hong Chen, Beijing (CN); Lu Wang, Beijing (CN); Haiqiang Jia, Beijing (CN); Ziguang Ma, Beijing (CN); Yang Jiang, Beijing (CN); Wenxin Wang, Beijing (CN)

(21) Appl. No.: 15/058,836

(22) Filed: Mar. 2, 2016

(30) Foreign Application Priority Data
Jul. 10, 2015 (CN) 201510404231.3

(51) Int. Cl. H01L 27/146; H01L 31/0304; H01L 31/109; H01L 31/0352

(52) U.S. Cl. CPC H01L 27/14652; H01L 31/035236; H01L 31/0304; H01L 31/109; H01L 31/035272

(57) ABSTRACT

The present application relates to a photodetector based on interband transition in quantum wells. The photodetector may include a first semiconductor layer having a first conduction type; a second semiconductor layer having a second conduction type different from the first conduction type; and a photon absorption layer arranged between the first semiconductor layer and the second semiconductor layer, the photon absorption layer including at least one quantum well layer and barrier layers arranged on both sides of each quantum well layer. The present application utilizes the modulating effect of a semiconductor PN junction on a photoelectric conversion process associated with quantum wells to significantly increase a current output of the photodetector based on the quantum well material.

### CROSS REFERENCE

The present application claims the benefit of, and priority to, Chinese Patent Application No. 201510404231.3, entitled “PHOTODETECTORS BASED ON INTERBAND TRANSITION IN QUANTUM WELLS”, filed on Jul. 10, 2015, the disclosure of which is incorporated herein in its entirety by reference.

### TECHNICAL FIELD

The present application generally relates to photodetectors, and in particular to photodetectors based on interband transition in quantum wells.

### BACKGROUND

Infrared photodetectors for a waveband of 800 nm to 1500 nm have significant applications in fields of local area network communication, long distance optical communication, low-light-level night vision, infrared thermal imaging, and the like. Such detectors typically consist of photodiodes such as PIN photodiodes and avalanche photodiodes. Photodiodes can only be sensitive to light having a wavelength corresponding to a band gap Eg of material for a photon absorption layer in the photodiodes or light having a wavelength slightly shorter. Therefore, the photon absorption layer of a photodiode has to be made of an appropriate material that corresponds to the waveband to be detected. A commonly-used photodiode may include an InGaAs layer on a Si, Ge, or InP substrate. Si has a band gap of 1.1 eV, and thus is sensitive to a wavelength ranging from visible light to near-infrared light. Ge has a band gap of 0.67 eV, and thus is sensitive to an infrared waveband. A photodiode having an InGaAs layer on an InP substrate is commonly used in optical communication applications of 1.3 μm to 1.55 μm waveband.

In order to guarantee sufficient photoabsorption efficiency, a relatively thick intrinsic absorption layer is often used in these commonly-used photodetectors. For example, the thickness of an intrinsic Si (i-Si) absorption layer needs to be up to 12 μm for infrared light of about 910 nm so as to guarantee that most of the light can be absorbed. However, the thick intrinsic absorption layer increases transit time of charge carriers, so that response speed of the photodiodes is decreased. Moreover, the relatively thick intrinsic absorption layer increases the cost for epitaxy process. For InP based InGaAs photodiodes, the InP substrate is expensive and has low mechanical strength. Thus, a low-cost photodetector has been expected in the market for a long time.

Therefore, there is a need to provide a photodetector having high efficiency and low noise and capable of being produced at a low cost.

### SUMMARY

It is generally believed that although the band gap of a strained quantum well (QW) can be regulated in a wide range, the thickness of the quantum well structure is generally thin due to strain accumulation, thus when a photodetector is designed to utilize interband transition effect of the quantum well, the quantum efficiency must be relatively low. Therefore, when there is an appropriate bulk material corresponding to a target wavelength, the quantum well material will usually not be considered.

The inventor found that a semiconductor PN junction has a significant influence on the photon absorption process in an absorption layer having a quantum well structure. The existence of the PN junction causes that after photons are absorbed via the quantum well interband transition process, the photo-generated carriers can be extracted more efficiently than expected. Such phenomenon makes the quantum well energy level act more like a continuous state rather than a localized state, which leads to a remarkable increment of the absorption coefficient. The discovery of the phenomenon makes it possible to realize photodetection by utilizing interband transition in quantum wells. It should be understood that in the present application, generally, the term “quantum well” may also mean quantum dots and superlattices in addition to quantum wells per se, and all of them are collectively referred to as “quantum well” just for illustrative and convenient purposes.

Therefore, an aspect of the present application is to provide a photodetector based on interband transition in quantum wells. The photodetector may comprise a first semiconductor layer having a first conduction type; a second semiconductor layer having a second conduction type different from the first conduction type; and a photon absorption layer arranged between the first and second semiconductor layers, the photon absorption layer including at least one quantum well layer and barrier layers arranged on both sides of each quantum well layer.

In an exemplary embodiment of the present application, the first semiconductor layer, the second semiconductor layer, and the barrier layer may include GaAs or AlGaAs, and the quantum well layer may include a material selected from a group including strained InGaAs quantum well, InAs quantum dot, and InAs/InGaAs quantum dots in well.

In an exemplary embodiment of the present application, the first semiconductor layer, the second semiconductor layer, and the barrier layer may include InP or InAlAs, and the quantum well layer may include a material selected from a group including strained InGaAs quantum well, InAs quantum dot, InAs/InGaAs quantum dots in well, InSb quantum well, InAsSb quantum well, InAs/GaSb superlattice, InAs/GaInSb superlattice, and InAs/InAsSb superlattice.

In an exemplary embodiment of the present application, the first semiconductor layer, the second semiconductor layer, and the barrier layer may include GaSb, and the quantum well layer may include a material selected from a group including strained InSb quantum well, InAs quantum well, InAsSb quantum well, InAs/GaSb superlattice, InAs/GaInSb superlattice, and InAs/InAsSb superlattice.

In an exemplary embodiment of the present application, the first semiconductor layer, the second semiconductor layer, and the barrier layer may include Si, and the quantum well layer may include a material selected from a group including Ge quantum well and GeSi quantum well.

In an exemplary embodiment of the present application, the photon absorption layer may include n quantum well layers, n being a positive integer between 1 and 200.

In an exemplary embodiment of the present application, each quantum well layer may have a thickness between 1 and 60 nm, and the barrier layer may have a thickness between 1 and 100 nm.

In an exemplary embodiment of the present application, the photon absorption layer may have a thickness between 50 nm and 20 μm.

In an exemplary embodiment of the present application, the photodetector may further comprise a multiplication layer arranged between the photon absorption layer and the first or second semiconductor layer.

In an exemplary embodiment of the present application, the photodetector may further comprise a charge layer arranged between the multiplication layer and the photon absorption layer.

In an exemplary embodiment of the present application, the photodetector may further comprise a graded layer arranged between the absorption layer and the charge layer.

The first conduction type may be one of P-type and N-type and the second conduction type may be the other of the P-type and the N-type. The quantum well layer and the barrier layers may be intrinsic or lightly doped semiconductor layers. The photodetector may be an infrared photodetector. The quantum well layer may experience interband transition between a valence band and a conduction band thererof when absorbing infrared light, so as to generate photo-generated carriers.

The exemplary embodiments of the present application utilize the semiconductor PN junction to modulate the photoabsorption and electroextraction processes associated with quantum wells such that quantum efficiency of the photodetector based on the quantum well material get significantly increased. After the incident light is absorbed via the interband transition in the quantum wells, photo-generated carriers enter a continuous state quickly under the modulating effect of the PN junction, so that a photocurrent is formed in a short time. Thus, a traditional two-step conversion process of photon to bound electron to free electron is changed to a one-step conversion process of photon to free electron, which directly increases photoelectric conversion capability.

Another aspect of the present application is to provide an optical communication system, comprising: an optical receiver for receiving an optical communication signal and converting the received signal into an electrical signal, the optical receiver including a photodetector comprising: a first semiconductor layer having a first conduction type; a second semiconductor layer having a second conduction type different from the first conduction type; and a photon absorption layer arranged between the first and second semiconductor layers, the photon absorption layer including at least one quantum well layer and barrier layers arranged on both sides of each quantum well layer.

In an exemplary embodiment of the present application, the first semiconductor layer, the second semiconductor layer, and the barrier layer may include GaAs or AlGaAs, and the quantum well layer may include a material selected from a group including strained InGaAs quantum well, InAs quantum dot, and InAs/InGaAs quantum dots in well.

In an exemplary embodiment of the present application, the first semiconductor layer, the second semiconductor layer, and the barrier layer may include InP or InAlAs, and the quantum well layer may include a material selected from a group including strained InGaAs quantum well, InAs quantum dot, InAs/InGaAs quantum dots in well, InAs/GaSb superlattice, InAs/GaInSb superlattice, and InAs/InAsSb superlattice.

In an exemplary embodiment of the present application, the first semiconductor layer, the second semiconductor layer, and the barrier layer may include Si, and the quantum well layer may include a material selected from a group including Ge quantum well and GeSi quantum well.

In an exemplary embodiment of the present application, the photon absorption layer may include n quantum well layers, n being a positive integer between 1 and 200.

In an exemplary embodiment of the present application, each quantum well layer may have a thickness between 1 and 50 nm, and each barrier layer may have a thickness between 1 and 100 nm.

In an exemplary embodiment of the present application, the photon absorption layer may have a thickness between 50 nm and 20 μm.

In an exemplary embodiment of the present application, the photodetector may further comprise: a multiplication layer arranged between the photon absorption layer and the first or second semiconductor layer; a charge layer arranged between the multiplication layer and the photon absorption layer; and a graded layer arranged between the absorption layer and the charge layer.

In the optical communication system of the present application, since the optical receiver uses the photodetector based on interband transition in quantum wells which enables a greater photocurrent as compared with a conventional photodetector, the optical communication system can achieve an increased overall performance. Moreover, the photodetector can be manufactured at a lower cost, so the cost of the optical communication system is reduced.

Yet another aspect of the present application is to provide an imaging device comprising a plurality of pixels. Each pixel may have a photodiode that includes: a first semiconductor layer of a first conduction type; a second semiconductor layer of a second conduction type different from the first conduction type; and a photon absorption layer arranged between the first and second semiconductor layers. The photon absorption layer may include at least one quantum well layer and barrier layers arranged on both sides of each quantum well layer.

In an exemplary embodiment of the present application, the quantum well layer may include a material selected from a group including strained InGaAs quantum well, InAs quantum well, InAs/InGaAs quantum dots in well, Ge quantum well, GeSi quantum well, InAsSb quantum well, InAs/GaSb superlattice, InAs/GaInSb superlattice, InAs/InAsSb superlattice, and strained InSb quantum well.

In an exemplary embodiment of the present application, the photodiode may further comprises a multiplication layer arranged between the photon absorption layer and the first or second semiconductor layer, a graded layer arranged between the multiplication layer and the photon absorption layer, and a charge layer arranged between the multiplication layer and the graded layer.

In an exemplary embodiment of the present application, the photodiode may be an infrared photodiode, and the quantum well layer may experience interband transition between a valence band and a conduction band thereof when absorbing infrared light so as to generate photo-generated carriers.

### BRIEF DESCRIPTION OF THE DRAWINGS

So that the present application can be understood in greater detail, a more particular description may be had by reference to features of various implementations, some of which are illustrated in appended drawings. The appended drawings, however, merely illustrate some pertinent features of the present application and are therefore not to be considered limiting, for the description may admit to other effective features.

FIG. 1 is a schematic diagram showing a structure of a photodetector in accordance with an embodiment of the present application.

FIG. 2 is a schematic diagram showing an energy band of the photodetector in FIG. 1.

FIG. 3 shows a photocurrent spectrum of a photodetector in accordance with an embodiment of the present application.

FIG. 4 is a schematic diagram showing a structure of a photodetector in accordance with another embodiment of the present application.

FIG. 5 is a schematic diagram showing a structure of a photodetector in accordance with another embodiment of the present application.

FIG. 6 is a schematic diagram showing a structure of a photodetector in accordance with another embodiment of the present application.

FIG. 7 is a schematic diagram showing a structure of a photodetector in accordance with another embodiment of the present application.

FIG. 8 is a schematic circuit diagram of a pixel unit of an imaging device in accordance with an embodiment of the present application.

FIG. 9 is a schematic diagram showing an optical communication system in accordance with an embodiment of the present application.

In accordance with common practice, the various features illustrated in the appended drawings may not be drawn to scale. Accordingly, dimensions of the various features may be arbitrarily expanded or reduced for clarity. In addition, some of the attached drawings may not depict all of components of a given device, apparatus, or system. Finally, like reference numerals may be used to denote like features throughout the specification and figures.

### DETAILED DESCRIPTION OF THE PREFERRED EMBODIMENT

Hereinafter, exemplary embodiments of the present application will be described with reference to the appended drawings. It should be understood that the exemplary embodiments are just used to show the principle of the present application, not to limit he present application to the exact form described. Instead, more or less details may be used to realize the present application. In the appended drawings, the similar elements are designated with the same reference numbers, and redundant description thereof may be omitted.

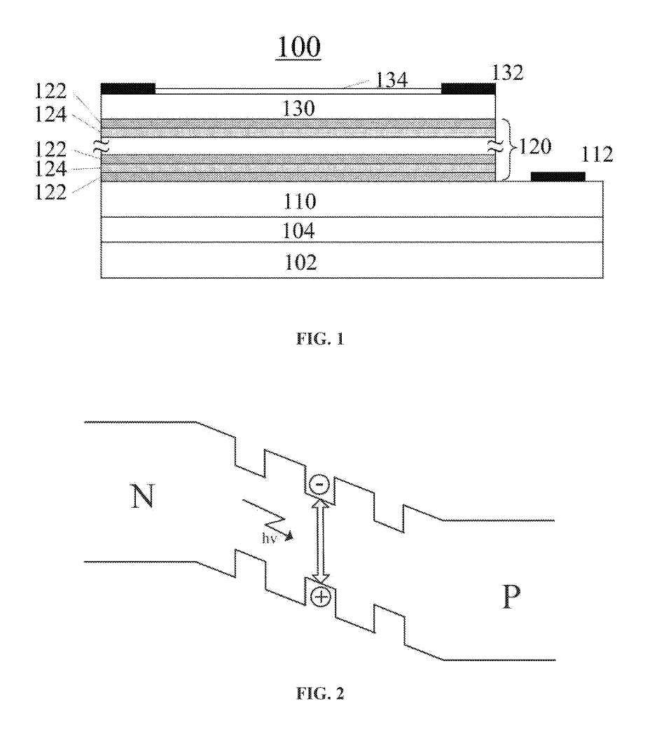

FIG. 1 is a schematic diagram showing a structure of a photodetector 100 in accordance with an embodiment of the present application. As shown in FIG. 1, the photodetector 100 may include a first semiconductor layer 110, an absorption layer 120, and a second semiconductor layer 130 arranged in sequence on a substrate 102. Such a structure of the photodetector 100 is similar to a conventional PIN-type photodiode except that its I-type absorption layer has a quantum well structure.

As shown in the FIG. 1, the substrate 102 may be any of substrates commonly used in the semiconductor field, for example, including but not limited to Si substrate, Ge substrate, SiC substrate, SOI substrate, sapphire substrate, ZnO substrate, GaAs substrate, InP substrate, GaSb substrate, and the like. An appropriate substrate 102 can be selected according to the material of the first semiconductor layer 110. For example, a GaAs substrate, an InP substrate, or a GaSb substrate can be used as the substrate 102 if the first semiconductor layer 110 is formed of GaAs, InP, or GaSb. Selecting the substrate 102 with the same material as the first semiconductor layer 110 can avoid lattice mismatch therebetween to the maximum extent and thus the epitaxial growth quality of the first semiconductor layer 110 can be ensured. In addition, the first semiconductor layer 110 can be epitaxially grown directly on the substrate 102, which saves process time and cost. On the other hand, a heterogeneous substrate may also be used. In such a case, realize the lattice match between the first semiconductor layer 110 and the substrate 102 which have different materials from each other, a buffer layer 104 can be grown on the substrate 102 first. Material and thickness of the buffer layer 104 can be selected according to the lattice constants of the substrate 102 and the first semiconductor layer 110. In an embodiment, the composition of the buffer layer 104 can be controlled, so that the buffer layer 104 lattice-matches the substrate 102 at one side thereof and lattice-matches the first semiconductor layer 110 at the other side thereof.

The first semiconductor layer 110 may be an N-type or P-type semiconductor layer epitaxially grown on the substrate 102. In the present application, respective semiconductor layers can be prepared by using various conventional thin film epitaxial growth or deposition methods, including but not limited to Hydride Vapor Phase Epitaxy (HVPE), Metal-Organic Chemical Vapor Deposition (MOCVD), Chemical Vapor Deposition (CVD), Molecular Beam Epitaxy (MBE), and the like. In some embodiments, the first semiconductor layer 110 may be formed of semiconductor materials such as GaAs, InP, GaSb, or the like. The first semiconductor layer 110 may have a thickness in a range from 100 nm to 10 μm.

The substrate 102 may be a semi-insulating substrate. As shown in FIG. 1, the first semiconductor layer 110 may be epitaxially grown on the substrate 102. In other embodiments, the substrate 102 may also be a conductive substrate. The first semiconductor layer 110 may be epitaxially grown on the substrate 102, or the substrate 102 itself may be directly used as the first semiconductor layer 110. For example, the substrate 102 may be a monocrystal conductive substrate of GaAs, InP, or GaSb, or a doped well region in a monocrystal non-conductive substrate.

The photon absorption layer 120 may be provided on the first semiconductor layer 110 using an epitaxial growth technology. Although not shown in FIG. 1, in order to enable lattice match between the photon absorption layer 120 and the first semiconductor layer 110, a buffer layer may further be formed therebetween. The photon absorption layer 120 may include alternately stacked barrier layers 122 and quantum well layers 124, with each quantum well layer 124 being sandwiched by two barrier layers 122. The quantum well layers 124 and the barrier layers 122 may be intrinsic or lightly doped semiconductor layers formed of materials appropriately selected according to the material of the first semiconductor layer 110. For example, if the first semiconductor layer 110 is an N-type or P-type GaAs or AlGaAs layer, the barrier layers 122 may be intrinsic GaAs or AlGaAs semiconductor layers, and the quantum well layers 124 may be, for example, strained InGaAs quantum well layers, InAs quantum dot layers, or InAs/InGaAs quantum dots in well layers. If the first semiconductor layer 110 is an N-type or P-type InP or InAlAs layer, the barrier layers 122 may be intrinsic InP or InAlAs semiconductor layers, and the quantum well layers 124 may be, for example, strained InGaAs quantum well layers, InAs quantum dot layers, InAs/InGaAs quantum dots in well layers, InSb quantum well layers, InAs/GaSb superlattices, InAs/GaInSb superlattices, InAs/InAsSb superlattices, InAsSb quantum well layers, or the like. If the first semiconductor layer 110 is an N-type or P-type GaSb layer, the barrier layers 122 may be intrinsic GaSb semiconductor layers, and the quantum well layers 124 may be, for example, strained InSb quantum well layers, InAs quantum well layers, InAsSb quantum well layers, InAs/GaSb superlattices, InAs/GaInSb superlattices, InAs/InAsSb superlattices, or the like. If the first semiconductor layer 110 is an N-type or P-type Si layer, the barrier layers 122 may be intrinsic Ge or GeSi semiconductor layers, and the quantum well layers 124 may be, for example, Ge quantum well layers, GeSi quantum well layers, or the like. These exemplified structures may have different usages depending on band gaps of quantum wells. For example, InSb quantum wells and InAsSb quantum wells may be used in fields of 3 to 5 μm infrared thermal imaging or the like, and other quantum wells may be used in fields of 1.1 to 1.55 μm optical communication, infrared thermal imaging, or the like.

Each barrier layer 122 may have a thickness between 1 and 100 nm, preferably between 2 and 50 nm, and more preferably between 3 and 30 nm. Each quantum well layer 124 may have a thickness between 1 and 60 nm, preferably between 2 and 40 nm, and more preferably between 3 and 20 nm. The photon absorption layer 120 may include a quantum well structure with n cycles. That is, the photon absorption layer 120 may include n quantum well layers 124 each being sandwiched by two barrier layers 122. There are n quantum well layers 124 and n+1 barrier layers 122 in total, where n is a positive integer between 1 and 200, preferably between 5 and 100, and more preferably between 10 and 50. Furthermore, the photon absorption layer 120 may have an overall thickness between 50 nm and 20 μm, preferably between 100 nm and 15 μm, and more preferably between 150 nm and 10 μm.

The second semiconductor layer 130 may epitaxially grow on the photon absorption layer 120. In a preferred embodiment, the second semiconductor layer 130 may have the same material as but the opposite conduction type to the first semiconductor layer 110. For example, if the first semiconductor layer 110 is an N-type or P-type GaAs layer, InP layer or GaSb layer, the second semiconductor layer 130 may be a P-type or N-type GaAs layer, InP layer or GaSb layer, respectively. The second semiconductor layer 130 may have a thickness of from 100 nm to 10 μm.

In addition, metal electrodes 112 and 132 may be formed on the first semiconductor layer 110 and the second semiconductor layer 130 respectively. The metal electrode 132 on the second semiconductor layer 130 may have a window pattern formed therein to transmit incident light to the absorption layer 120 therebelow. An anti-reflecting film 134, which may be formed of, for example, SiN or SiO₂, may be formed on the second semiconductor layer 130 within the window so as to increase the amount of light impinging onto the photon absorption layer 120.

Some specific examples of the photodetector 100 according to the embodiment shown in FIG. 1 will be described below. For purposes of clear and full disclosure, a lot of details are given in these examples. However, it will be understood that the present application is not limited to these specific details, and many variations can be made without departing from the scope as defined in the appended claims.

### Example 1

An N-type GaAs first semiconductor layer 110 including dopant Si at a concentration of 1×10¹⁸ cm⁻³ may be epitaxially grown to a thickness of 300 nm on a GaAs semi-insulating substrate 102 directly by using the Metal-Organic Chemical Vapor Deposition (MOCVD) method. Then, a photon absorption layer 120 may be epitaxially grown on the first semiconductor layer 110. The photon absorption layer 120 may include alternate intrinsic GaAs barrier layers 122 and strained InGaAs quantum well layers 124 and terminate with the intrinsic GaAs barrier layers 122 on both sides thereof. The intrinsic GaAs barrier layers 122 each may have a thickness of 30 nm, the strained InGaAs quantum well layers 124 each may have a thickness of 20 nm, and the number of the strained InGaAs quantum well layers 124 may be 30.

Next, a P-type GaAs semiconductor layer 130 including dopant Mg at a concentration of 5×10¹⁷ cm⁻³ may be epitaxially grown to a thickness of 200 nm on the photon absorption layer 120. Then, the stacked layers may be patterned by way of photolithograph and etching processes, and metal electrodes 112 and 132 may be formed on the first semiconductor layer 110 and the second semiconductor layer 130 respectively.

### Example 2

A P-type AlGaAs first semiconductor layer 110 including dopant Mg at a concentration of 5×10¹⁷ cm⁻³ may be epitaxially grown to a thickness of 300 nm on a GaAs conductive substrate 102 by using the Metal-Organic Chemical Vapor Deposition (MOCVD) method. Then, a photon absorption layer 120 may be epitaxially grown on the first semiconductor layer 110. The photon absorption layer 120 may include alternate intrinsic AlGaAs barrier layers 122 and InAS quantum dot layers 124 and terminate with the intrinsic AlGaAs barrier layers 122 on both sides thereof. The intrinsic AlGaAs barrier layers 122 each may have a thickness of 30 nm, the InAS quantum dot layers 124 each may have a thickness of 20 nm, and the number of the InAS quantum dot layers 124 may be 20. Next, an N-type AlGaAs semiconductor layer 130 including dopant Si at a concentration of 1×10¹⁸ cm⁻³ may be epitaxially grown to a thickness of 200 nm on the photon absorption layer 120. Then, the stacked layers may be patterned by way of photolithograph and etching processes, and metal electrodes 112 and 132 may be formed on the first semiconductor layer 110 and the second semiconductor layer 130 respectively.

### Example 3

An N-type AlGaAs first semiconductor layer 110 including dopant Si at a concentration of 5×10¹⁸ cm⁻³ may be epitaxially grown to a thickness of 400 nm on a GaAs semi-insulating substrate 102 directly by using the Metal-Organic Chemical Vapor Deposition (MOCVD) method. Then, a photon absorption layer 120 may be epitaxially grown on the first semiconductor layer 110. The photon absorption layer 120 may include alternate intrinsic AlGaAs barrier layers 122 and InAS/InGaAs quantum dots in well layers 124 and terminate with the intrinsic AlGaAs barrier layers 122 on both sides thereof. The intrinsic AlGaAs barrier layers 122 each may have a thickness of 30 nm, the quantum dot layers 124 each may have a thickness of 30 nm, and the number of the quantum dot layers 124 may be 20. Next, a P-type AlGaAs semiconductor layer 130 including dopant Zn at a concentration of 5×10¹⁷ cm⁻³ may be epitaxially grown to a thickness of 200 nm on the photon absorption layer 120. Then, the stacked layers may be patterned by way of photolithograph and etching processes, and metal electrodes 112 and 132 may be formed on the first semiconductor layer 110 and the second semiconductor layer 130 respectively.

### Example 4

An N-type InP first semiconductor layer 110 including dopant Si at a concentration of 1×10¹⁸ cm⁻³ may be epitaxially grown to a thickness of 300 nm on an InP conductive substrate 102 by using the Molecular Beam Epitaxy (MBE) method. Then, a photon absorption layer 120 may be epitaxially grown on the first semiconductor layer 110. The photon absorption layer 120 may include alternate intrinsic InP barrier layers 122 and strained InGaAs quantum well layers 124 and terminate with the intrinsic InP barrier layers 122 on both sides thereof. The intrinsic InP barrier layers 122 each may have a thickness of 30 nm, the strained InGaAs quantum well layers 124 each may have a thickness of 20 nm, and the number of the strained InGaAs quantum well layers 124 may be 20. Next, a P-type InP semiconductor layer 130 including dopant Mg at a concentration of 5×10¹⁷ cm⁻³ may be epitaxially grown to a thickness of 200 nm on the photon absorption layer 120. Then, the stacked layers may be patterned by way of photolithograph and etching processes, and metal electrodes 112 and 132 may be formed on the first semiconductor layer 110 and the second semiconductor layer 130 respectively.

### Example 5

An N-type InAlAs first semiconductor layer 110 including dopant Si at a concentration of 1×10¹⁸ cm⁻³ may be epitaxially grown to a thickness of 300 nm on an InP semi-insulating substrate 102 by using the Molecular Beam Epitaxy (MBE) method. Then, a photon absorption layer 120 may be epitaxially grown on the first semiconductor layer 110. The photon absorption layer 120 may include alternate intrinsic InAlAs barrier layers 122 and InAs quantum dot layers 124 and terminate with the intrinsic InAlAs barrier layers 122 on both sides thereof. The intrinsic InAlAs barrier layers 122 each may have a thickness of 30 nm, the InAs quantum dot layers 124 each may have a thickness of 20 nm, and the number of the InAs quantum dot layers 124 may be 20. Next, a P-type InAlAs semiconductor layer 130 including dopant Mg at a concentration of 5×10¹⁷ cm⁻³ may be epitaxially grown to a thickness of 200 nm on the photon absorption layer 120. Then, the stacked layers may be patterned by way of photolithograph and etching processes, and metal electrodes 112 and 132 may be formed on the first semiconductor layer 110 and the second semiconductor layer 130 respectively.

### Examples 6-8

The structures of examples 6-8 may be basically the same as the example 4 or 5, except that the quantum well layers 124 utilizes InAs/InGaAs quantum dots in well layers, InSb quantum well layers, and InAsSb quantum well layers respectively. Therefore, the repetitive description thereof is omitted herein.

### Example 9

An N-type GaSb first semiconductor layer 110 including dopant Te at a concentration of 1×10¹⁸ cm⁻³ may be epitaxially grown to a thickness of 500 nm on a GaSb semi-insulating substrate 102 directly by using the Molecular Beam Epitaxy (MBE) method. Then, a photon absorption layer 120 may be epitaxially grown on the first semiconductor layer 110. The photon absorption layer 120 may include alternate intrinsic GaSb barrier layers 122 and strained InSb quantum well layers 124 and terminate with the intrinsic GaSb barrier layers 122 on both sides thereof. The intrinsic GaSb barrier layers 122 each may have a thickness of 30 nm, the strained InSb quantum well layers 124 each may have a thickness of 20 nm, and the number of the strained InSb quantum well layers 124 may be 30. Next, a P-type GaSb semiconductor layer 130 including dopant Be at a concentration of 5×10¹⁷ cm⁻³ may be epitaxially grown to a thickness of 300 nm on the photon absorption layer 120. Then, the stacked layers may be patterned by way of photolithograph and etching processes, and metal electrodes 112 and 132 may be formed on the first semiconductor layer 110 and the second semiconductor layer 130 respectively.

### Examples 10-11

The structures of examples 10-11 may be basically the same as the example 9, except that the quantum well layer 124 utilizes InAs quantum well layers and InAsSb quantum well layers respectively.

### Example 12

An N-type Si first semiconductor layer 110 including dopant P at a concentration of 1×10¹⁸ cm⁻³ may be epitaxially grown to a thickness of 300 nm on a Si semi-insulating substrate 102 by using the Molecular Beam Epitaxy (MBE) method. Then, a photon absorption layer 120 may be epitaxially grown on the first semiconductor layer 110. The photon absorption layer 120 may include alternate intrinsic Si barrier layers 122 and Ge quantum well layers 124 and terminate with the intrinsic Si barrier layers 122 on both sides thereof. The intrinsic Si barrier layers 122 each may have a thickness of 30 nm, the Ge quantum well layers 124 each may have a thickness of 20 nm, and the number of the Ge quantum well layers 124 may be 20. Next, a P-type Si semiconductor layer 130 including dopant B at a concentration of 5×10¹⁷ cm⁻³ may be epitaxially grown to a thickness of 200 nm on the photon absorption layer 120. Then, the stacked layers may be patterned by way of photolithograph and etching processes, and metal electrodes 112 and 132 may be formed on the first semiconductor layer 110 and the second semiconductor layer 130 respectively.

### Example 13

An N-type Si first semiconductor layer 110 including dopant P at a concentration of 1×10¹⁸ cm⁻³ may be epitaxially grown to a thickness of 300 nm on a Si semi-insulating substrate 102 by using the Molecular Beam Epitaxy (MBE) method. Then, a photon absorption layer 120 may be epitaxially grown on the first semiconductor layer 110. The photon absorption layer 120 may include alternate intrinsic Si barrier layers 122 and GeSi quantum well layers 124 and terminate with the intrinsic Si barrier layers 122 on both sides thereof. The intrinsic Si barrier layers 122 each may have a thickness of 30 nm, the GeSi quantum well layers 124 each may have a thickness of 20 nm, and the number of the GeSi quantum well layers 124 may be 20. Next, a P-type Si semiconductor layer 130 including dopant B at a concentration of 5×10¹⁷ cm⁻³ may be epitaxially grown to a thickness of 200 nm on the photon absorption layer 120. Then, the stacked layers may be patterned by way of photolithograph and etching processes, and metal electrodes 112 and 132 may be formed on the first semiconductor layer 110 and the second semiconductor layer 130 respectively.

Only some example manufacturing methods have been described above briefly. Specific manufacturing processes for such semiconductor layers and quantum well layers are already known to those skilled in the art, and thus, the detailed description thereof is omitted herein in order to avoid obscuring the present application unnecessarily.

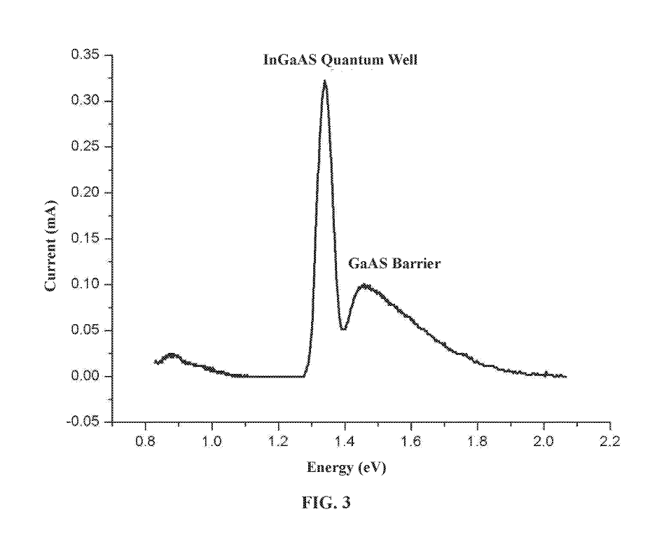

FIG. 2 shows an energy band diagram of the photodetector 100 shown in FIG. 1. As shown in FIG. 2, the photodetector 100 operates under a reverse bias voltage, and the barrier layers 122 and the quantum well layers 124 in the photon absorption layer 120 have different band gaps. Specifically, the band gap of the quantum well layers 124 may be less than that of the barrier layers 122. When photons having energy hv pass through the anti-reflecting film 134 and the second semiconductor layer 130 and impinge onto the quantum well layers 124 in the photon absorption layer 120, interband transition between a valence band and a conduction band occurs, generating electron-hole pairs. Under the combined effect of a built-in electric field and a bias electric field, the electrons will move towards the N-type semiconductor layer, and the holes will move towards the P-type semiconductor layer, generating a photo-generated current. Under the modulating effect of the semiconductor PN junction, photo-generated carriers enter a continuous state quickly. Thus, a traditional two-step conversion process of photon to bound electron to free electron is changed to an one-step conversion process of photon to free electron directly, which significantly increases the efficiency of photoelectric conversion associated with the quantum wells.

FIG. 3 shows a photocurrent spectrum of the photodetector of Example 1 mentioned above. In this photodetector, as described above, the quantum well layers 124 are formed of strained InGaAs and the barrier layers 122 are formed of intrinsic GaAs material. As shown in FIG. 3, the photocurrent is much higher at energy of about 1.35 eV corresponding to InGaAs quantum wells than at energy of about 1.47 eV corresponding to GaAs barriers. The former are more than three times higher than the latter. Although the physical theory for quantum wells generating a high photocurrent is still not very clear, it is believed that the modulating effect of the PN junction contribute to enabling the quantum well layers to realize a high efficiency of photoelectric conversion through the interband transition.

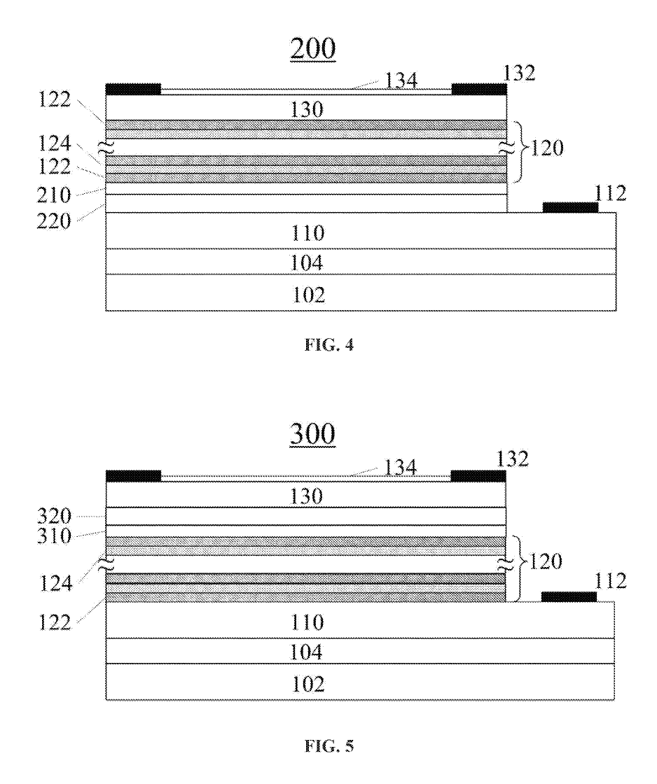

A photodetector 200 in accordance with another embodiment of the present application will be described below with reference to FIG. 4. In the photodetector 200 shown in FIG. 4, elements the same as those in the photodetector 100 shown in FIG. 1 are designated with the same reference numbers, and redundant description thereof will be omitted herein.

As shown in FIG. 4, the photodetector 200 further includes a graded layer 210 and a multiplication layer 220 arranged between the first semiconductor layer 110 and the photon absorption layer 120. The multiplication layer 220 is arranged on the first semiconductor layer 110, and the graded layer 210 is arranged on the multiplication layer 220.

When the photo-generated carriers generated in the photon absorption layer 120, such as electrons and holes, move towards the N region (for example, the first semiconductor layer 110) and the P region (for example, the second semiconductor layer 130) respectively, carries such as electrons pass through the multiplication layer 220. The multiplication layer 220 may be an intrinsic (without intentional doping) semiconductor layer that has a different conduction type from the semiconductor layer it contacts (here, the first semiconductor layer 110), and it forms a high electric field region. In the multiplication layer 220, electrons are accelerated to an average velocity high enough so that the energy carried by them exceeds threshold impact energy, so as to trigger a lattice impact ionization effect which generates secondary electron-hole pairs. The newly-generated electron-hole pairs are also accelerated in the multiplication layer 220 so that the impact ionization continues to occur. This enables the photodetector to have an internal gain which may be used to amplify the original photo-generated carriers.

The graded layer 210 may be arranged between the absorption layer 120 and the multiplication layer 220. When the absorption layer 120 and the multiplication layer 220 have a relatively large band gap difference, charge carriers moving towards the multiplication layer 220 may be blocked and thus their velocity may be decreased significantly, so that multiplication efficiency of the multiplication layer 220 and response time of the photodetector are adversely affected. In order to address this problem, the graded layer 210 may be arranged between the absorption layer 120 and the multiplication layer 220. The graded layer 210 may have a band gap which is between that of the absorption layer 120 and that of the multiplication layer 220. Moreover, the graded layer 210 may have its composition gradually changed so as to match its energy band with the absorption layer 120 at one side and with the multiplication layer 220 at the other side. As such, the photodetector 200 may have advantages of high speed, high quantum efficiency, and good gain performance at the same time, so as to realize a more practical value.

Although in the embodiment shown in FIG. 4, the multiplication layer 220 is arranged between the first semiconductor layer 110 and the absorption layer 120, it can be understood that the multiplication layer may also be arranged between the second semiconductor layer 130 and the absorption layer 120, as shown in FIG. 5. A photodetector 300 shown in FIG. 5 may include a graded layer 310 arranged on the absorption layer 120 and a multiplication layer 320 arranged on the graded layer 310. The second semiconductor layer 130 may be arranged on the multiplication layer 320. Semiconductor materials may have different ionization rate for electrons and holes, and therefore, the multiplication layer may be located according to its material.

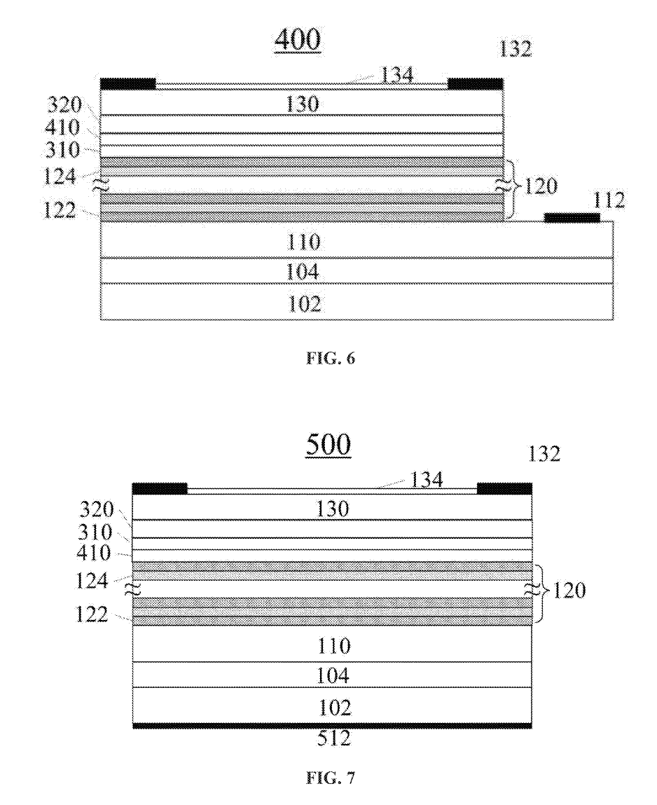

FIG. 6 shows a photodetector 400 in accordance with another embodiment of the present application. The photodetector 400 is basically the same as the photodetector 300 shown in FIG. 5, except that a charge layer 410 is further arranged between the multiplication layer 320 and the graded layer 310. The charge layer 410 may also be referred to as an electric field control layer. It can regulate the intensity of the electric field in the absorption layer to guarantee a short carrier transit time and thus realize high response speed. Meanwhile, it allows the intrinsic multiplication layer alone to control the width of the multiplication region to realize high gain-bandwidth product.

Although not shown, it may be understood that a charge layer may also be arranged between the graded layer 210 and the multiplication layer 220 in the photodetector 200 shown in FIG. 4.

In the embodiments described above, the electrodes 112 and 132 are both formed on the same side of the substrate. In some other embodiments, the electrodes 112 and 132 may also be formed on two opposite sides of the substrate respectively. As shown in FIG. 7, a photodetector 500 may have a structure basically the same as that of the photodetector 400 shown in FIG. 6, except an electrode 512. The electrode 512 may be arranged on the lower surface of the conductive substrate 102 and covers the entire surface. The electrode 512 may also be used as a reflecting layer, which reflects light passing through the photon absorption layer 120 back to the photon absorption layer 120, so as to increase the photoelectric conversion efficiency. In some other embodiments, light may also be incident on the lower surface of the substrate, pass through the substrate 102 and the first semiconductor layer 110, and impinge onto the photon absorption layer 120. In this case, the electrode 512 may be patterned to have a window allowing light to pass therethrough, and an anti-reflecting layer 134 may be formed on the surface of the substrate 102 in the window. The electrode 132 may cover the entire upper surface of the second semiconductor layer 130, and be used as a light reflecting layer.

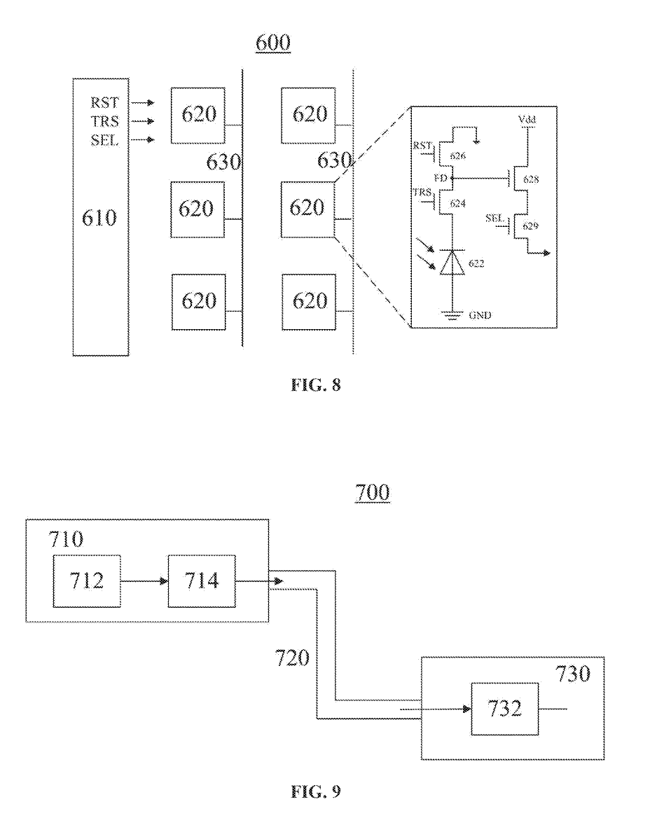

The photodetectors of the present application may be used in various photoelectric devices and circuits. For example, the photodetectors with strained InGaAs quantum wells, InAs quantum wells, InAs/InGaAs quantum dots in wells, Ge quantum wells, or GeSi quantum wells may be used in 1.1 to 1.55 μm optical communication, infrared imaging, or the like, and the photodetectors with InAs/GaSb superlattices, InAs/GaInSb superlattices, InAs/InAsSb superlattices, InAsSb quantum wells, or strained InSb quantum wells may be used in 3 to 5 μm infrared thermal imaging, or the like. FIG. 8 shows an imaging device 600 in accordance with an embodiment of the present application. The imaging device 600 may include a row controller 610, a plurality of pixels 620 arranged in rows and columns, and a plurality of bit lines 630 extending in the column direction.

Each pixel 620 may include a photodiode 622, which may be any one of the photodetectors described above. When the photodiode 622 senses infrared light, it generates signal charges. A transfer transistor 624 receives a transfer control signal TRS from the row controller 610 and turns on, so that the signal charges generated by the photodiode 622 may be transferred to a floating diffusion zone FD. An amplifier transistor 628 may amplify the signal charges in the floating diffusion zone FD, output an amplified signal to the bit line 630 via a selecting transistor 629. When the selecting transistor 629 receives a selection control signal SEL from the row controller 610, it turns on so that the output signal from the amplifier transistor 628 may be provided to the bit line 630. In another embodiment, the selecting transistor 629 may be omitted. The pixel 620 may also include a reset transistor 626. When the reset transistor 626 receives a reset control signal RST from the row controller 610, it turns on so that the electric potential of the floating diffusion zone FD is set to a predetermined electric potential, for example, to the ground potential.

FIG. 9 shows an optical communication system in accordance with an embodiment of the present application. As shown in FIG. 9, the optical communication system 700 may include an optical transmitter 710, an optical fiber 720, and an optical receiver 730. The optical transmitter 710 may include a light source 712, for example, a laser device. Laser emitted by the light source 712 may be modulated by a modulator 714 to carry communication signals, and then be sent to the optical fiber 720. The optical receiver 730 may receive the optical communication signals from the optical fiber 720. The optical receiver 730 may include a photodetector 732, which may be any one of those photodetectors described above that can be used in optical communication. The photodetector 732 may convert the optical communication signals into electrical signals for further processing, for example, for a demodulator (not shown) to demodulate useful communication signals.

Although the present application has been described above with reference to the exemplary embodiments, the present application is not limited thereto. It will be apparent to those skilled in the art that various alternations and modifications in forms and details can be made without departing from the scope and spirit of the present application. The scope of the present application is only defined by the appended claims or the equivalents thereof.

1. A photodetector, comprising:
a first semiconductor layer having a first conduction type;
a second semiconductor layer having a second conduction type different from the first conduction type; and
a photon absorption layer arranged between the first semiconductor layer and the second semiconductor layer, the photon absorption layer including at least one quantum well layer and barrier layers arranged on both sides of each quantum well layer.

2. The photodetector of claim 1, wherein the first semiconductor layer, the second semiconductor layer, and the barrier layer include GaAs or AlGaAs, and the quantum well layer includes a material selected from a group including strained InGaAs quantum well, InAs quantum dot, and InAs/InGaAs quantum dots in quantum well.

3. The photodetector of claim 1, wherein the first semiconductor layer, the second semiconductor layer, and the barrier layer include InP or InAlAs, and the quantum well layer includes a material selected from a group including strained InGaAs quantum well, InAs quantum dot, InAs/InGaAs quantum dots in quantum well, strained InSb quantum well, InAsSb quantum well, InAs/GaSb superlattice, InAs/GaInSb superlattice, and InAs/InAsSb superlattice.

4. The photodetector of claim 1, wherein the first semiconductor layer, the second semiconductor layer, and the barrier layer include GaSb, and the quantum well layer includes a material selected from a group including strained InSb quantum well, InAs quantum well, InAsSb quantum well, InAs/GaSb superlattice, InAs/GaInSb superlattice, and InAs/InAsSb superlattice.

5. The photodetector of claim 1, wherein the first semiconductor layer, the second semiconductor layer, and the barrier layer include Si, and the quantum well layer includes a material selected from a group including Ge quantum well and GeSi quantum well.

6. The photodetector of claim 1, wherein the first conduction type is one of a P-type and an N-type and the second conduction type is the other of the P-type and the N-type.

7. The photodetector of claim 1, wherein the quantum well layer and the barrier layers are intrinsic or lightly doped semiconductor layers.

8. The photodetector of claim 1, wherein the photon absorption layer includes n quantum well layers, n being a positive integer between 1 and 200, each quantum well layer has a thickness between 1 and 60 nm, and each barrier layer has a thickness between 1 and 100 nm.

9. The photodetector of claim 1, further comprising:
a multiplication layer arranged between the photon absorption layer and the first or second semiconductor layer.

10. The photodetector of claim 9, further comprising:
a graded layer arranged between the multiplication layer and the photon absorption layer.

11. The photodetector of claim 10, further comprising:
a charge layer arranged between the multiplication layer and the graded layer.

12. The photodetector of claim 1, wherein the quantum well layer experiences interband transition between a valence band and a conduction band thereof when absorbing light, thereby generating photo-generated carriers.

13. An optical communication system, comprising:
an optical receiver for receiving an optical signal and converting the received optical signal into an electrical signal, the optical receiver including a photodetector comprising:
a first semiconductor layer having a first conduction type;
a second semiconductor layer having a second conduction type different from the first conduction type; and
a photon absorption layer arranged between the first semiconductor layer and the second semiconductor layer, the photon absorption layer including at least one quantum well layer and barrier layers arranged on both sides of each quantum well layer.

14. The optical communication system of claim 13, wherein the quantum well layer includes a material selected from a group including strained InGaAs quantum well, InAs quantum well, InAs/InGaAs quantum dots in well, Ge quantum well, GeSi quantum well, InAs/GaSb superlattice, InAs/GaInSb superlattice, and InAs/InAsSb superlattice.

15. The optical communication system of claim 13, wherein the quantum well layer and the barrier layers are intrinsic or lightly doped semiconductor layers.

16. The optical communication system of claim 13, wherein the photodetector further comprises:
a multiplication layer arranged between the photon absorption layer and the first or second semiconductor layer;
a graded layer arranged between the multiplication layer and the photon absorption layer; and
a charge layer arranged between the multiplication layer and the graded layer.

17. An imaging device comprising a plurality of pixels, each pixel including a photodiode comprising:
a first semiconductor layer having a first conduction type;
a second semiconductor layer having a second conduction type different from the first conduction type; and
a photon absorption layer arranged between the first semiconductor layer and the second semiconductor layer, the photon absorption layer including at least one quantum well layer and barrier layers arranged on both sides of each quantum well layer.

18. The imaging device of claim 17, wherein the quantum well layer includes a material selected from a group including strained InGaAs quantum well, InAs quantum well, InAs/InGaAs quantum dots in well, Ge quantum well, GeSi quantum well, InAsSb quantum well, InAs/GaSb superlattice, InAs/GaInSb superlattice, InAs/InAsSb superlattice, and strained InSb quantum well.

19. The imaging device of claim 17, wherein the photodiode further comprises:
a multiplication layer arranged between the photon absorption layer and the first or second semiconductor layer;
a graded layer arranged between the multiplication layer and the photon absorption layer; and
a charge layer arranged between the multiplication layer and the graded layer.

20. The imaging device of claim 17, wherein the quantum well layer experiences interband transition between a valence band and a conduction band thereof when absorbing light, thereby generating photo-generated carriers.
